(19) United States
(12) Patent Application Publication
(10) Pub. No.: US 2012/0146038 A1
(43) Pub. Date: Jun. 14, 2012

(54) SEMICONDUCTOR DEVICE, ACTIVE MATRIX SUBSTRATE, AND DISPLAY DEVICE

(75) Inventor: Hidehito Kitakado, Osaka-shi (JP)

(73) Assignee: SHARP KABUSHIKI KAISHA, Osaka-shi, Osaka (JP)

(21) Appl. No.: 13/392,273

(22) PCT Filed: Aug. 26, 2010
(86) PCT No.: PCT/JP2010/064511

§ 371 Date: Feb. 24, 2012

(30) Foreign Application Priority Data
Aug. 28, 2009 (JP) 2009-197911

(51) Int. Cl. H01L 29/786

(52) U.S. Cl. 257/59; 257/E29.273

(57) ABSTRACT

Provided are a semiconductor device that can achieve leakage current reduction irrespective of an ambient temperature, an active matrix substrate in which such a semiconductor device is used, and a display device. In a switching portion (semiconductor device) (18) including a plurality of thin film transistors connected in series, there are provided a plurality of gate electrodes (g1 to g4); channel regions (30) and low-concentration impurity-doped regions (29) that are included in a silicon layer (semiconductor layer) (SL) provided below the plurality of gate electrodes (g1 to g4), and are provided in the plurality of thin film transistors, respectively; and a bottom gate electrode (21) provided below the silicon layer (SL). To the bottom gate electrode (29), a signal in the same phase as that of a signal for the gate electrodes (g1 to g4) is supplied.

### TECHNICAL FIELD

The present invention relates to a semiconductor device provided with thin film transistors, an active matrix substrate in which such a semiconductor device is used, and a display device.

### BACKGROUND ART

Recently, a liquid crystal display device, for example, has been used as a flat panel display characterized in thinness, light weight, etc. as compared with a conventional cathode-ray tube, widely in liquid crystal televisions, monitors, portable telephones, etc. Known as such a liquid crystal display device is a liquid crystal display device in which an active matrix substrate having the following configuration is used in a liquid crystal panel as a display panel: a plurality of data lines (source lines) and a plurality of scanning lines (gate lines) are arranged in matrix, and in the vicinity of intersections between the data lines and the scanning lines, switching elements such as thin film transistors (hereinafter abbreviated as “TFT”), and pixels having pixel electrodes connected to the switching elements are provided, whereby the switching elements and pixels are arranged in matrix.

In the active matrix substrate as described above, generally, thin film transistors for peripheral circuits are provided integrally, in addition to the above-described pixel-driving thin film transistors as switching elements. Further, the following has been proposed: in the case where the active matrix substrate is used in a touch-panel-equipped liquid crystal display device, or a liquid crystal display device having illuminance sensors (ambient sensors), photodiodes as optical sensors (thin film diodes: TFDs) are provided integrally in the active matrix substrate, in addition to the above-described thin film transistors for driving pixels and for peripheral circuits. Thus, in an active matrix substrate, a plurality of semiconductor devices having thin film transistors and photodiodes are used.

Further, in a semiconductor device as described above, recently, the reduction of leakage current of a thin film transistor has been demanded, so as to meet the request for the reduction of power consumption in, for example, a liquid crystal panel incorporating the above-described optical sensors, a liquid crystal panel incorporating pixel memories, etc. To cope with this, for a conventional semiconductor device, it has been proposed that channel regions and channel-adjacent regions of thin film transistors are covered with data lines having light shielding properties, light-shielding films provided below the thin film transistors, or the like, as described in, for example, JP2000-91581A; by doing so, external light is blocked so that to leakage current reduction is attempted.

### DISCLOSURE OF INVENTION

A conventional semiconductor device as described above, however, has a problem that the leakage current reduction is impossible in some cases depending on ambient temperature. To be more specific, a leakage current of a thin film transistor increases due to, not only irradiation with external light, but also an increase in ambient temperature. Therefore, in a conventional semiconductor device, when the ambient temperature rises, a leakage current increases due to thermal excitation occurring in thin film transistors, with which this attempt for the leakage current reduction fails.

In order to suppress a leakage current of a thin film transistor, a low-concentration impurity-doped region (LDD region: lightly doped drain region) having a higher resistance than in a source region and a drain region may be provided in at least one of the following two regions: a region between a channel region and the source region; and a region between the channel region and the drain region. In the case where such a low-concentration impurity-doped region is provided, however, another problem of a decrease in a current driving power (i.e., ON current) for a thin film transistor arises. In other words, in a conventional semiconductor device, if a leakage current is suppressed, this causes lack of an ON current, and if an ON current is increased, this causes a leakage current to increase also; thus, the conventional semiconductor device cannot breaks away from the relationship of trade-off between the suppression of a leakage current and the increase of an ON current. As a result, an increase in a leakage current due to the above-described thermal excitation cannot be prevented.

In light of the above-described problem, it is an object of the present invention to provide a semiconductor device that can achieve leakage current reduction irrespective of an ambient temperature, an active matrix substrate in which such a semiconductor device is used, and a display device.

In order to achieve the above-described object, a semiconductor device according to the present invention is characterized in including: a plurality of thin film transistors connected in series; gate electrodes that are provided in the plurality of thin film transistors, respectively; a semiconductor layer provided below a plurality of the gate electrodes; channel regions formed in the semiconductor layer, the channel regions being provided in the plurality of thin film transistors, respectively; low-concentration impurity-doped regions formed in the semiconductor layer, the low-concentration impurity-doped regions being adjacent to the channel regions; a bottom gate electrode provided below the channel regions; and a light shielding film that shields the channel regions and the low-concentration impurity-doped regions from light, wherein, in a state where a voltage is being applied to the gate electrodes, a voltage is applied to the bottom gate electrode.

The present invention makes it possible to provide a semiconductor device that can achieve leakage current reduction irrespective of an ambient temperature, and an active matrix substrate in which such a semiconductor device is used, and a display device.

### BRIEF DESCRIPTION OF DRAWINGS

FIG. 1 explains a liquid crystal display device according to Embodiment 1 of the present invention.

FIG. 2 explains a configuration of a liquid crystal panel shown in FIG. 1.

FIG. 3 is a circuit diagram showing an equivalent circuit of a switching portion shown in FIG. 2.

FIG. 4 is a time chart showing the case where a gate electrode signal and a bottom gate electrode signal are identical to each other.

FIG. 5 is a time chart showing the case where a falling time of a gate electrode signal and a falling time of a bottom gate electrode signal are different from each other.

FIG. 6 is a cross-sectional view showing a specific configuration of the aforementioned switching portion.

FIG. 7 is a graph showing the relationship between a source/drain voltage and a leakage current in a thin film transistor.

FIG. 8 is a graph showing the relationship between a voltage applied to the bottom gate electrode and a resistance value of a low-concentration impurity-doped region in the aforementioned switching portion.

FIG. 9 is a cross-sectional view showing a specific configuration of a switching portion according to Embodiment 2 of the present invention.

FIG. 10 is a cross-sectional view showing a specific configuration of a switching portion according to Embodiment 3 of the present invention.

FIG. 11 is a cross-sectional view showing a specific configuration of a switching portion according to Embodiment 4 of the present invention.

FIG. 12 is a cross-sectional view showing a specific configuration of a modified example of the switching portion according to Embodiment 1 of the present invention.

FIG. 13 is a cross-sectional view showing a specific configuration of another modified example of the switching portion according to Embodiment 1 of the present invention.

### EMBODIMENTS

A semiconductor device according to one embodiment of the present invention includes: a plurality of thin film transistors connected in series; gate electrodes that are provided in the plurality of thin film transistors, respectively; a semiconductor layer provided below a plurality of the gate electrodes; channel regions formed in the semiconductor layer, the channel regions being provided in the plurality of thin film transistors, respectively; low-concentration impurity-doped regions formed in the semiconductor layer, the low-concentration impurity-doped regions being adjacent to the channel regions; a bottom gate electrode provided below the channel regions; and a light shielding film that shields the channel regions and the low-concentration impurity-doped regions from light, wherein, in a state where a voltage is being applied to the gate electrodes, a voltage is applied to the bottom gate electrode (first configuration).

In the first configuration, in a state where a gate voltage is being applied to the gate electrodes, a bottom gate voltage is applied to the bottom gate electrode, whereby a resistance of the low-concentration impurity-doped regions can be reduced significantly. This makes it possible to increase the number of thin-film transistors connected in series, so that a source/drain voltage per one transistor decreases. As a result, even when an ambient temperature rises, a leakage current can be reduced surely by the light shielding film.

Further, in the first configuration, the application of the voltage to the gate electrodes, and the application of the voltage to the bottom gate electrode, preferably start at the same time (second configuration).

Still further, in either the first configuration or the second configuration, the application of the voltage to the gate electrodes, and the application of the voltage to the bottom gate electrode, desirably end at different times, respectively (third configuration). With the third configuration, problems due to the so-called field-through phenomenon can be prevented.

Still further, in any one of the first to third configurations, preferably, the bottom gate electrode also functions as the light shielding film (fourth configuration). With the fourth configuration, it is possible to prevent the structure of the semiconductor device from becoming complex and bulky. Besides, a semiconductor device that can be easily fabricated can be configured easily.

Still further, in any one of the first to fourth configurations, desirably, the light shielding film is a lower light shielding film that is provided below the semiconductor layer and shields the channel regions and the low-concentration impurity-doped regions from light (fifth configuration). With the fifth configuration, light from below the channel regions and the low-concentration impurity-doped regions can be blocked. As a result, it is possible to prevent an increase in a leakage current due to this light.

Still further, in any one of the first to fifth configurations, the light shielding film is preferably an upper light shielding film that is provided above the semiconductor layer and shields the channel regions and the low-concentration impurity-doped regions from light (sixth configuration). With the sixth configuration, light from above the channel regions and the low-concentration impurity-coped regions can be blocked by the upper light shielding film. This prevents an increase in a leakage current due to this light.

Still further, in the sixth configuration, preferably, a voltage is applied to the upper light shielding film, in a state where a voltage is being applied to the gate electrodes (seventh configuration). With the seventh configuration, the resistance of the low-concentration impurity-doped regions in a state where the thin film transistors are turned on can be reduced further. This makes it possible to easily increase the number of the thin film transistors connected in series. As a result, a leakage current can be reduced further. Besides, a current driving power (ON current) of the thin film transistors can be increased easily.

Still further, in the seventh configuration, preferably, the application of the voltage to the gate electrodes, and the application of the voltage to the upper light shielding film, start at the same time (eighth configuration).

Still further, in the seventh or eighth configuration, preferably, the application of the voltage to the gate electrodes, and the application of the voltage to the upper light shielding film, end at different times, respectively (ninth configuration). With the ninth configuration, problems due to the so-called field-through phenomenon can be prevented.

Still further, any one of the sixth to ninth configurations preferably further includes a source electrode provided at an end side of the semiconductor layer; and a drain electrode provided at the other end side of the semiconductor layer, wherein the upper light shielding film is formed with the same material in the same layer as those for the source electrode and the drain electrode (tenth configuration). In the case of the tenth configuration, the upper light shielding film, as well as the source electrode and the drain electrode, can be formed at the same time. As a result, a semiconductor device that can be easily fabricated can be configured easily.

Still further, in any one of the sixth to tenth configurations, the gate electrodes and the upper light shielding film may be formed so as to overlap each other in a vertical direction, whereby the gate electrodes and the upper light shielding film are capacitively coupled with each other (eleventh configuration). With the eleventh configuration, each load capacitance of the plurality of gate electrodes can be reduced.

Still further, in any one of the first to eleventh configurations, preferably, in the semiconductor layer, a dimension of each of the low-concentration impurity-doped regions in a direction in which the plurality of thin film transistors are connected is set to a predetermined dimension or smaller (twelfth configuration). With the twelfth configuration, a decrease in the ON current can be prevented, even when the resistance of the low-concentration impurity-doped regions 36 is set higher and the number of thin film transistors connected in series is increased. Even if the number of thin film transistors connected in series is increased, the total of resistances of the low-concentration impurity-doped regions can be prevented from increasing. The ratio of an area occupied by the thin film transistors in the semiconductor device can be decreased.

Still further, in any one of the first to twelfth configurations, the bottom gate electrode may be divided into a plurality of pieces so that the pieces are located below the channel regions, respectively (thirteenth configuration). With the thirteenth configuration, each load capacitance of the plurality of gate electrodes can be reduced.

Still further, an active matrix substrate according to one embodiment of the present invention is characterized in that any one of the aforementioned semiconductor devices is used (fourteenth configuration).

In the fourteenth configuration, the semiconductor device that can achieve leakage current reduction irrespective of an ambient temperature is used. As a result, an active matrix substrate characterized by low power consumption can be configured easily.

A display device according to one embodiment of the present invention is characterized in that any one of the aforementioned semiconductor device is used (fifteenth configuration).

In the fifteenth configuration, the semiconductor device that can achieve leakage current reduction irrespective of an ambient temperature is used. As a result, a display device characterized by low power consumption can be configured easily.

Hereinafter, preferable embodiments of the semiconductor device, the active matrix substrate, and the display device of the present invention are explained with reference to drawings. It should be noted that in the following explanation, the present invention is explained by referring to an exemplary case where the present invention is applied to a pixel-driving switching portion used in an active matrix substrate in a liquid crystal display device. Dimensions of constituent members shown in the drawings do not necessarily faithfully show dimensions of actual constituent members, dimension ratios of the actual constituent members, and the like.

### Embodiment 1

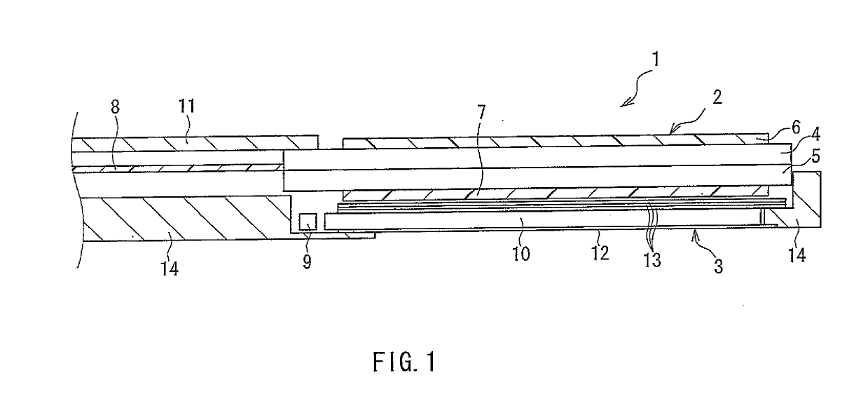

FIG. 1 explains a liquid crystal display device according to Embodiment 1 of the present invention. A liquid crystal display device 1 of the present embodiment shown in FIG. 1 includes a liquid crystal panel 2 provided so that a viewed side thereof (display surface side) is the upper side as viewed in FIG. 1, and a backlight device 3 that is provided on a non-display surface side (lower side as viewed in FIG. 1) of the liquid crystal panel 2 and that generates illumination light for irradiating the liquid crystal panel 2.

The liquid crystal panel 2 includes a color filter substrate 4 and an active matrix substrate 5 that composes a pair of substrates, and polarization plates 6 and 7 that are provided on outer side surfaces of the color filter substrate 4 and the active matrix substrate 5, respectively. Between the color filter substrate 4 and the active matrix substrate 5, a liquid crystal layer is interposed, though the illustration of the liquid crystal layer is omitted. A plate-like transparent glass material, or a transparent synthetic resin such as an acrylic resin, is used for forming the color filter substrate 4 and the active matrix substrate 5. Films of resins, such as TAC (triacetyl cellulose), or PVA (polyvinyl alcohol) are used for the polarization plates 6 and 7. These polarization plates 6 and 7 are attached over the color filter substrate 4 and the active matrix substrate 5, respectively, so as to cover at least an effective display region on the display surface provided on the liquid crystal panel 2.

The active matrix substrate 5 forms one of the above-described pair of substrates. Pixel electrodes, thin film transistors (TFT), etc. are formed on the active matrix substrate 5, in a space between the active matrix substrate 5 and the above-described liquid crystal layer, so as to correspond to a plurality of pixels included in the display surface of the liquid crystal panel 2 (details are to be described later). On the active matrix substrate 5, as described later in detail, switching portions (semiconductor devices) of the present invention that include the aforementioned thin film transistors are provided for each pixel. On the other hand, the color filter substrate 4 forms the other one of the pair of substrates. On the color filter substrate 4, color filters, a counter electrode, etc. are formed in a space between the color filter substrate 4 and the above-described liquid crystal layer (not shown).

Further, the liquid crystal panel 2 is provided with a FPC (flexible printed circuit) 8 connected to a control device (not shown) that performs driving control for the liquid crystal panel 2. In the liquid crystal panel 2, the liquid crystal layer is caused to operate pixel by pixel. Thus, the display surface is driven pixel by pixel. As a result, a desired image is displayed on the display surface.

It should be noted that the liquid crystal panel 2 may have an arbitrary liquid crystal mode and an arbitrary pixel configuration. Besides, the driving mode of the liquid crystal panel 2 may be arbitrary. In other words, any liquid crystal panel that is capable of displaying information can be used as the liquid crystal panel 2. Therefore, a detailed structure of the liquid crystal panel 2 is not shown in FIG. 1, and explanation of the same is omitted also.

The backlight device 3 includes a light emitting diode 9 as a light source, and a light guide plate 10 arranged so as to face the light emitting diode 9. In the backlight device 3, the light emitting diode 9 and the light guide plate 10, in a state where the liquid crystal panel 2 is provided above the light guide plate 10, are sandwiched between bezels 14 each of which has an L-letter-shaped cross section. Further, on the color filter substrate 4, a case 11 is mounted. In this way, the backlight device 3 is assembled with the liquid crystal panel 2 so as to be integrally provided with the liquid crystal panel 2. This is the configuration of the transmissive-type liquid crystal display device 1 in which illumination light from the backlight device 3 is incident on the liquid crystal panel 2.

For the light guide plate 10, a synthetic resin such as a transparent acrylic resin is used. The light from the light emitting diode 9 enters the light guide plate 10. On a side of the light guide plate 10 opposite to the liquid crystal panel 2 (a facing side), a reflection sheet 12 is provided. On a side of the light guide plate 10 toward the liquid crystal panel 2 (a light emission side), an optical sheet 13 such as a lens sheet or a diffusion sheet is provided. Thus, the light from the light emitting diode 9, guided in a predetermined light guiding direction (a direction from left to right as viewed in FIG. 1) in the light guide plate 10, is converted into the aforementioned illumination light that is planar and has a uniform illuminance, and is given to the liquid crystal panel 2.

It should be noted that the above explanation explains a configuration in which the edge-light-type backlight device 3, having the light guide plate 10, is used, but the present embodiment is not limited to this configuration. A direct-type backlight device may be used. Alternatively, a backlight device having a light source other than a light emitting diode, such as a cold cathode fluorescent tube or a hot cathode fluorescent tube, can be used.

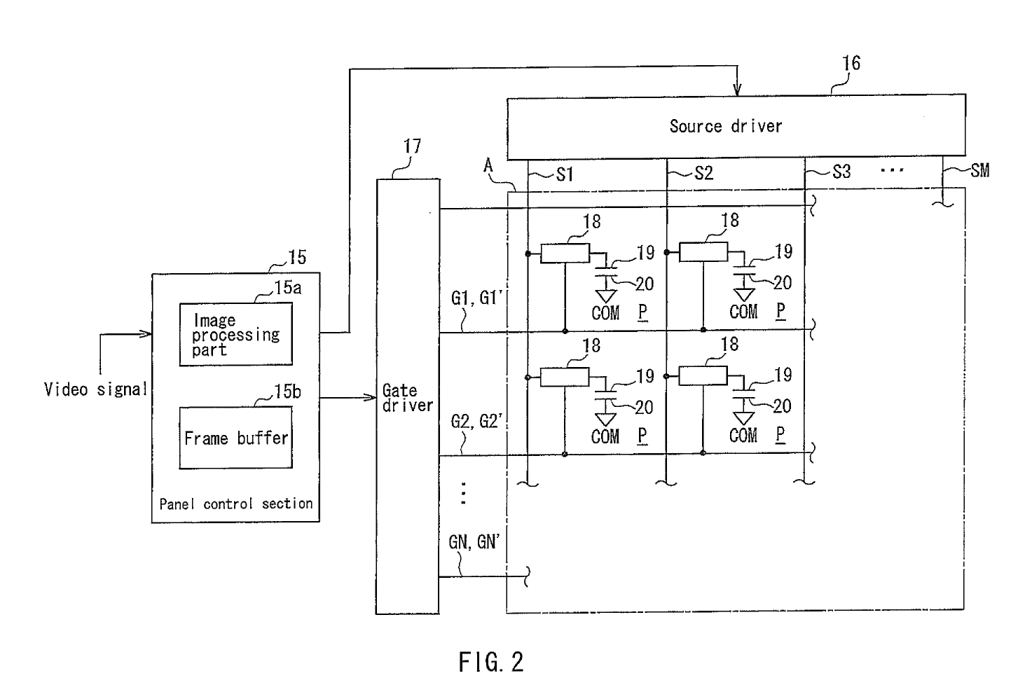

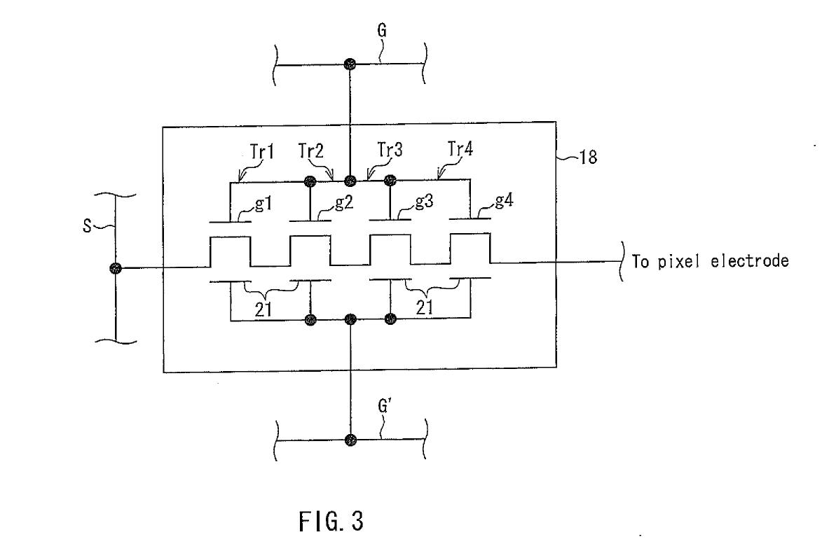

Next, the liquid crystal panel 2 of the present embodiment is explained below specifically, with reference to FIGS. 2 and 3.

FIG. 2 explains the configuration of the liquid crystal panel shown in FIG. 1. FIG. 3 is a circuit diagram showing an equivalent circuit of a switching portion shown in FIG. 2.

In FIG. 2, the liquid crystal display device 1 (FIG. 1) is provided with a panel control section 15, a source driver 16, and a gate driver 17. The panel control section 15 performs driving control of the aforementioned liquid crystal panel 2 (FIG. 1) as a display section for displaying information such as characters and images. The source driver 16 and the gate driver 17 operate based on instruction signals from the panel control section 15.

The panel control section 15 is provided in the control device. To the panel control section 15, video signals are input from outside the liquid crystal display device 1. The panel control section 15 includes an image processing portion 15a, and a frame buffer 15b. The image processing portion 15a performs predetermined image processing with respect to input video signals, and generates respective instruction signals for the source driver 16 and the gate driver 17. The frame buffer 15b is capable of storing display data for one frame contained in the video signals that are input therein. The panel control section 15 performs driving control for the source driver 16 and the gate driver 17 based on the video signals input therein. Thus, information corresponding to the video signals input therein is displayed on the liquid crystal panel 2.

The source driver 16 and the gate driver 17 are provided on the active matrix substrate 5. More specifically, the source driver 16 is provided in a region outside an effective display region A of the liquid crystal panel 2 as a display panel, along a horizontal direction of the liquid crystal panel 2, on a surface of the active matrix substrate 5. The gate driver 17 is provided in a region outside the effective display region A, along a vertical direction of the liquid crystal panel 2, on the surface of the active matrix substrate 5.

The source driver 16 and the gate driver 17 are driving circuits for driving a plurality of pixels P provided on the liquid crystal panel 2, pixel by pixel. To the source driver 16 and the gate driver 17, a plurality of source lines S1 to SM (M is an integer of 2 or more, and the source lines are hereinafter generally denoted by “S”) and a plurality of gate lines G1 to GN (N is an integer of 2 or more, and the gate lines are hereinafter generally denoted by “G”) are connected, respectively. These source lines S and gate lines G compose data lines and scanning lines, respectively. The source lines S and the gate lines G are arranged in matrix so as to cross each other on a substrate (not shown) made of a transparent glass material or a transparent synthetic resin included in the active matrix substrate 5. More specifically, the source lines S are provided on the substrate so as to be in parallel with a column direction of the matrix (the vertical direction of the liquid crystal panel 2). The gate lines G are provided on the substrate so as to be in parallel with a row direction of the matrix (the horizontal direction of the liquid crystal panel 2).

Further, on the active matrix substrate 5, a plurality of bottom gate lines G1′ to GN′ (N′ is an integer of 2 or more, and the bottom gate lines are hereinafter generally denoted by “G′”) are provided, so as to be parallel with the plurality of gate lines G1 to GN. These bottom gate lines G′ are connected to the gate driver 17, like the gate lines G. The bottom gate lines G′ supply, to bottom gate electrodes that will be described later, the same scanning signal (gate signal) as that supplied to gate electrodes connected to the gate lines G, which will be described later.

Further, in the vicinity of each of the intersections between the source lines S, and the gate lines G as well as the bottom gate lines G′, there are provided a switching portion 18 for a pixel electrode in which the semiconductor device of the present invention is used, and the aforementioned pixel P having a pixel electrode 19 connected to the switching portion 18. In each pixel P, a common electrode 20 is provided facing the pixel electrode 19, with the liquid crystal layer being interposed between the common electrode 20 and the pixel electrode 19. In other words, in the active matrix substrate 5, the switching portion 18, the pixel electrode 19, and the common electrode 20 are provided for each pixel.

As shown in FIG. 3, a plurality, for example, four, of thin film transistors Tr1, Tr2, Tr3, and Tr4 are connected in series in the switching portion 18. In the switching portion 18, respective gate electrodes g1, g2, g3, and g4 of the thin film transistors Tr1 to Tr4 are connected to the gate line G. Further, a source electrode and a drain electrode of the switching portion 18 are connected to the source line S and the pixel electrode 19, respectively. Further, in the switching portion 18, the bottom gate electrode 21 is connected to the bottom gate line G′.

Still further, in the switching portion 18 of the present embodiment, as the bottom gate electrode 21, one bottom gate electrode that is integrally provided is used with respect to the four gate electrodes g1 to g4. Further, the bottom gate electrode 21 also functions as a light shielding film for blocking illumination light from the backlight device 3 (details will be described later).

With reference to FIG. 2 again, on the active matrix substrate regions of the pixels P are formed in regions defined in matrix by the source lines S, and the gate lines G as well as the bottom gate lines G′. The plurality of pixels P include red (R) pixels, green (G) pixels, and blue (B) pixels. These pixels RGB are arranged, for example, in this order, in parallel with the gate lines G1 to GN. Further, with a color filter layer (described later) provided on the color filter substrate 4, the pixels RGB performs display of corresponding colors.

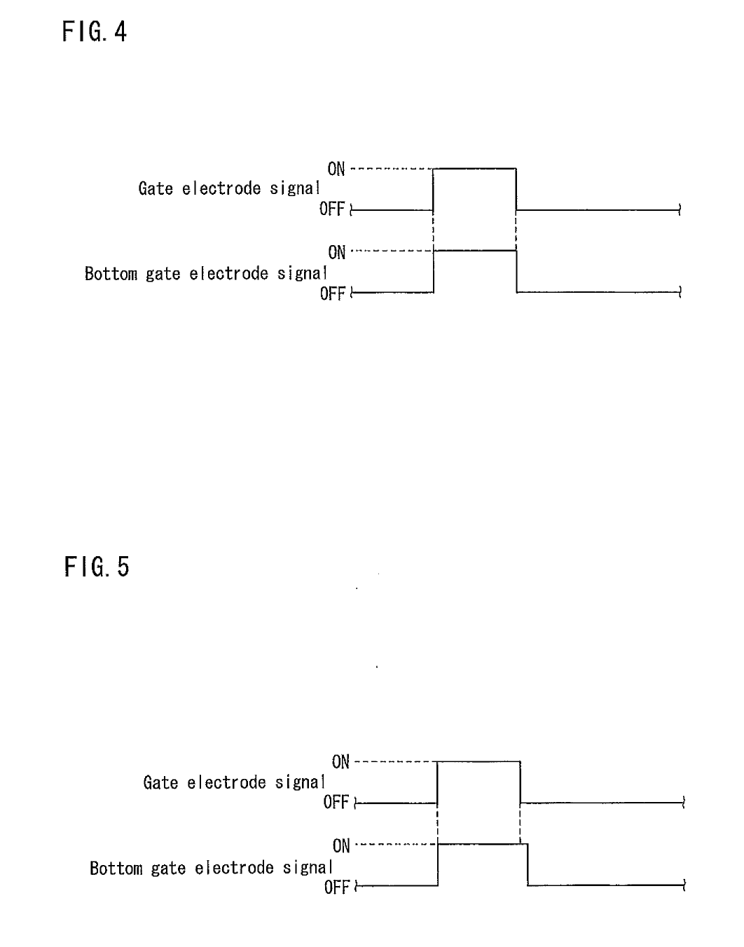

Still further, on the active matrix substrate 5, in response to an instruction signal from the image processing portion 15a, the gate driver 17 outputs, to the gate lines G1 to GN sequentially, a scanning signal (gate signal) that causes the gate electrodes g1 to g4 in the corresponding switching portion 18 to turn on. Still further, as shown in FIG. 4, the gate driver 17 sequentially outputs, to the bottom gate lines G1′ to GN′, the same gate signal to the bottom gate electrode 21 in the corresponding switching portion 18, at the same timings as those for the gate lines G1 to GN that are paired with the bottom gate lines G1′ to GN′, respectively.

In FIG. 4, the gate signal output to the gate electrode g1 to g4 (gate electrode signal), and the gate signal output to the bottom gate electrode 21 (bottom gate electrode signal) are identical to each other regarding the magnitude of the driving voltage, the rising time, and the falling time, but a requirement is only that in the switching portion 18, the bottom gate electrode signal is output in a state where the gate electrode signal is being output. Therefore, the gate electrode signal and the bottom gate electrode signal may be different regarding at least one of the magnitude of the driving voltage, the rising time, and the falling time. Here, the falling time of the bottom gate electrode signal is preferably different from the falling time of the gate electrode signal. More specifically, for example, as shown in FIG. 5, the gate electrode signal and the bottom gate electrode signal are set so that after the former falls, the latter falls. It is also possible, of course, that after the bottom gate electrode signal falls, the gate electrode signal falls.

Further, in response to instruction signals from the image processing portion 15a, the source driver 16 outputs data signals (voltage signals (gray scale voltages)) corresponding to illuminances (gray scales) of display images to corresponding ones of the source lines S1 to SM.

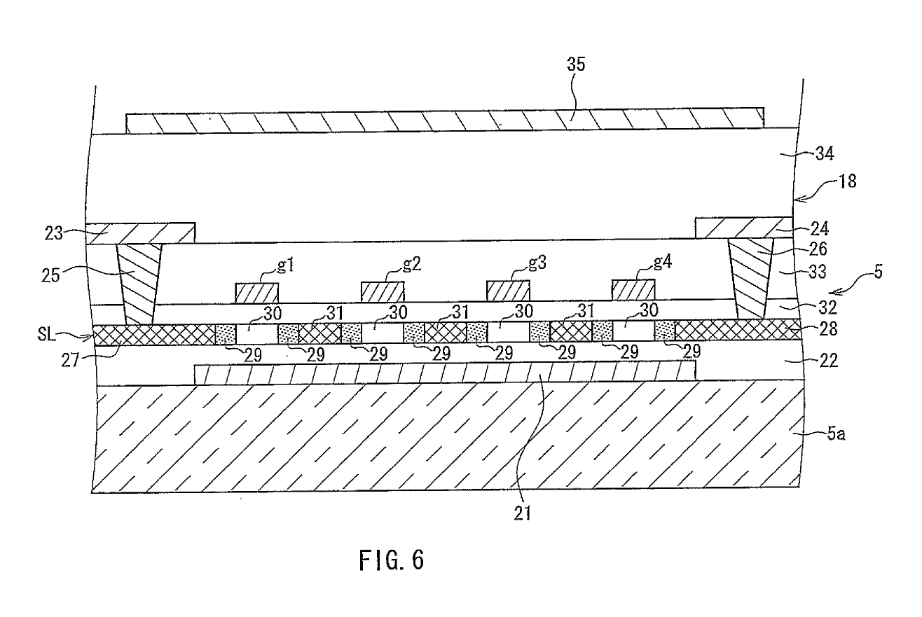

Hereinafter, the switching portion 18 is explained more specifically, with reference to FIG. 6.

FIG. 6 is a cross-sectional view showing a specific configuration of the above-described switching portion.

As shown in FIG. 6, in the active matrix substrate 5, the switching portion 18 is provided at each pixel on a substrate main body 5a made of a glass substrate. The switching portion 18 includes the aforementioned gate electrodes g1 to g4, a silicon layer SL as a semiconductor layer provided below these gate electrodes g1 to g4, and the bottom gate electrode 21 provided below the silicon layer SL. In the switching portion 18, a gate insulation film 32 is provided between the gate electrodes g1 to g4 and the silicon layer SL. Thus, the gate insulation film 32 electrically insulates these gate electrodes g1 to g4 and the silicon layer SL from each other. Further, in the switching portion 18, a base insulation film 22 is provided between the silicon layer SL and the bottom gate electrode 21. Thus, the base insulation film 22 electrically insulates the silicon layer SL and the bottom gate electrode 21 from each other.

Further, in the switching portion 18, the aforementioned source electrode 23 and the aforementioned drain electrode 24 are formed on a first interlayer film 33 that is formed so as to cover the gate electrodes g1 to g4. The source electrode 23 is connected to a source region 27 provided in the silicon layer SL, via a contact hole 25. The drain electrode 24 is connected to a drain region 28 provided in the silicon layer SL, via a contact hole 26.

Further, in the switching portion 18, N-type transistors are used for the thin film transistors Tr1 to Tr4. In other words, in the silicon layer SL, there are provided high-concentration regions (indicated by cross-hatching in FIG. 6) 27, 28, and 31 to which an N-type impurity, for example, phosphorus, is doped at a high concentration, and low-concentration impurity-doped regions (LDD regions: lightly doped drain regions, indicated by stippling in FIG. 6) 29 to which an N-type impurity is doped at a low concentration, and channel regions 30. More specifically, in the silicon layer SL, in an area between the source region 27 and the drain region 28, the following are provided: channel regions 30 provided for the thin film transistors Tr1 to Tr4 each, immediately below the gate electrodes g1 to g4; and low-concentration impurity-doped regions 29 provided adjacent to the channel regions 30. Further, in the silicon layer SL, in spaces between adjacent ones of the thin film transistors Tr1 to Tr 4, high-concentration regions 31 are provided, and low-concentration impurity-doped regions 29 are formed so that each high-concentration region 31 is interposed between the low-concentration impurity-doped regions 29.

Still further, in the switching portion 18, the bottom gate electrode 21 is formed below the silicon layer SL between an end of the source region 27 and an end of the drain region 28, as shown in FIG. 6. For this bottom gate electrode 21, a non-transparent electrode material is used, as will be described in detail later. With this configuration, the bottom gate electrode 21 functions also as a light shielding film for preventing light from the lower side as viewed in FIG. 6, for example, illumination light from the backlight device 3, from entering the low-concentration impurity-doped regions 29 and the channel regions 30. In the switching portion 18, therefore, a leakage current due to the aforementioned illumination light can be suppressed. Further, in the switching portion 18, as will be described in detail later, the leakage current reduction can be attempted by the bottom gate electrode 21, irrespective of the ambient temperature.

Still further, in the switching portion 18, an upper light shielding film 35 is provided on a surface of a second interlayer film 34 that is formed on the first interlayer film 33. This upper light shielding film 35 is provided above the gate electrodes g1 to g4, in an area between the source electrode 23 and the drain electrode 24 as shown in FIG. 6, so as to shield the low-concentration impurity-doped regions 29 and the channel regions 30 from light. In other words, the upper light shielding film 35 can prevent light from the upper side as viewed in FIG. 6 from entering the low-concentration impurity-doped regions 29 and the channel regions 30.

Here, the following description specifically explains a method for forming the switching portion 18.

A film of a metal such as molybdenum or tungsten is formed by sputtering on the substrate main body 5a as shown in FIG. 6. Thereafter, patterning is carried out by photolithography, whereby the bottom gate electrode 21 is formed. A specific film thickness of this bottom gate electrode 21 is about 100 to 200 nm.

Next, as the base insulation film 22, for example, an SiN film and an SiO₂ film are sequentially formed by CVD (chemical vapor deposition) so as to have a film thickness of 100 nm each. Thereafter, an amorphous silicon film is formed on the base insulation film 22 so as to have film thickness of 50 nm, and is subjected to laser crystallization so as to become polysilicon. This polysilicon is doped with boron as a channel dope for threshold adjustment.

Then, an SiO₂ film is formed as the gate insulation film 32 on the polysilicon so as to have a film thickness of 80 nm. Thereafter, a film of a metal such as molybdenum or tungsten is formed on the gate insulation film 32, and patterning is carried out, whereby the gate electrodes g1 to g4 are formed. Using these gate electrodes g1 to g4 as a mask, an N-type impurity, for example, phosphorus, is doped at a low concentration, so as to form the low-concentration impurity-doped regions 29. Then, after a photoresist is formed for ensuring a longitudinal dimension (LDD length) of the low-concentration impurity-doped regions 29, phosphorus is doped in order to form the source region 27, the drain region 28, and the high-concentration regions 31.

Here, in the low-concentration impurity-doped regions 29, a doping amount is adjusted so that the regions have a sheet resistance of about 50 kΩ to 150 kΩ (for example, the doping amount is 1×10¹³ to 1×10¹⁴/cm²). The doping is performed at a doping amount adjusted so as to counteract the previously doped P-type impurity (boron) for a channel dope, whereby the N-type low-concentration impurity-doped regions 29 are formed. In the source region 27, the drain region 28, and the high-concentration regions 31, phosphorous is doped at an amount of about 1×10¹⁵/cm² so that these regions have a sheet resistance of 1 kΩ or less. Thereafter, in order to activate impurities, a heat treatment at 500° C. to 600° C. is performed for one hour. It should be noted that in order to shorten the heat treatment time, a heat treatment at 650° C. to 700° C. may be carried out for several minutes by, for example, a lamp annealing device.

Next, as the first interlayer film 33, an SiO₂ film and an SiN film are formed to a thickness of about 100 nm to 300 nm each. Thereafter, the contact holes 25 and 26 for connection with the source electrode 23 and the drain electrode 24, respectively, are formed therein. Then, a metal, for example, Al or an alloy of the same, or a laminated film of the same for the source electrode 23, the drain electrode 24, and lines are formed in film forms, and patterning is carried out.

Subsequently, as the second interlayer film 34, an SiO₂ film and an SiN film are formed to a thickness of about 100 nm to 300 nm each. Alternatively, an acrylic resin may be formed to a thickness of 1 μm to 2 μm. Thereafter, a film of a metal such as molybdenum or aluminum is formed by sputtering on the second interlayer film 34. Then, patterning is performed by photolithography, whereby the upper light shielding film 35 is formed. A specific film thickness of the upper light shielding film 35 is about 100 to 200 nm.

Finally, though not illustrated in the drawings, for the liquid crystal display device 1, a planarizing film is formed with a resin film or the like, after lines are formed, in order that the pixel electrode 19 is to be formed thereon. On this flattening film, a transparent electrode (e.g., ITO) that will become the pixel electrode 19 is formed. In some cases, Al, Ag, or an ally of the same is formed as a reflection electrode on the ITO.

It should be noted that the above description explains a forming method in the case where the thin film transistors Tr1 to Tr4 are formed with N-type transistors. In the case where the thin film transistors Tr1 to Tr4 are formed with P-type transistors, a P-type impurity, for example, boron, is used as an impurity used for forming the source region 27 and the drain region 28. Besides, since driver circuits in the peripheral area around the panel can be formed also by the above-described forming method, the switching portion 18 of the present structure can be adopted to a switching element in which leakage current reduction is required.

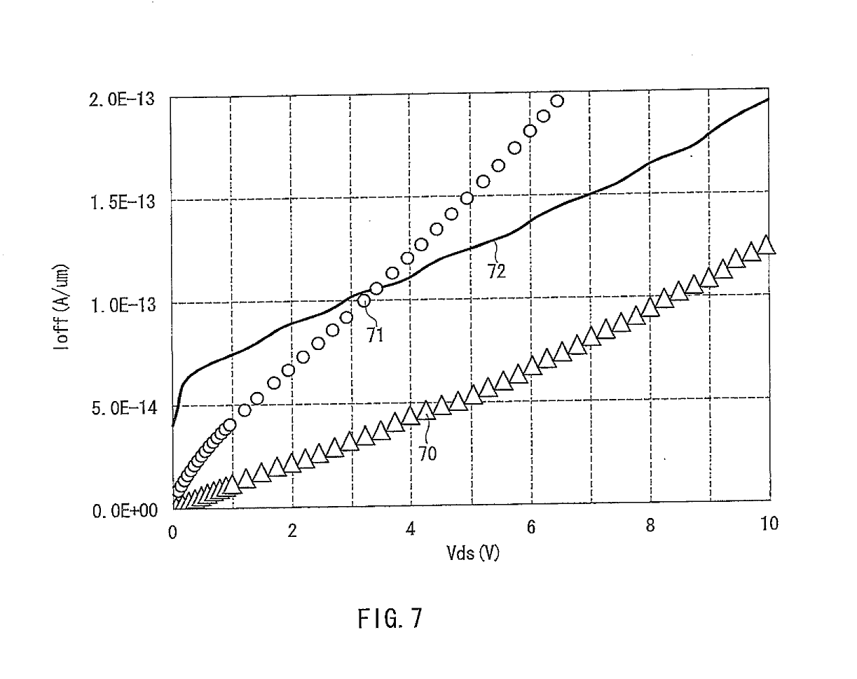

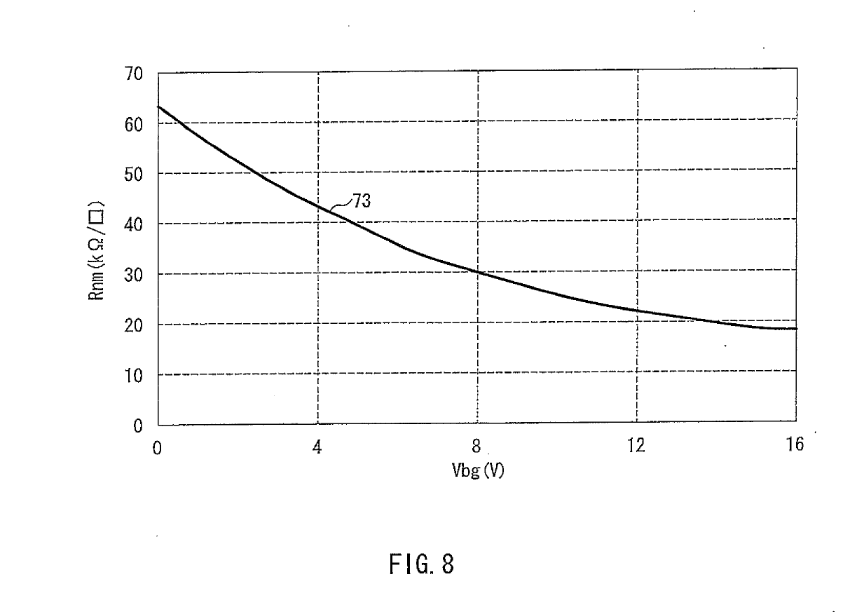

The following specifically explains an effect of the leakage current reduction by the bottom gate electrode 21 in the switching portion 18, referring to FIGS. 7 and 8.

FIG. 7 is a graph showing the relationships between a source/drain voltage and a leakage current in a thin film transistor. FIG. 8 is a graph showing the relationship between a voltage applied to the bottom gate electrode 21 and a resistance of the low-concentration impurity-doped region 29 at the switching portion 18.

In FIG. 7, a voltage Vds plotted on the horizontal axis indicates a source/drain voltage per one of the thin film transistors Tr1 to Tr4 connected in series. In FIG. 7, curves 70 and 71 indicate relationships between the voltage Vds and a leakage current Ioff when the ambient temperature around the thin film transistors is 40° C. and when it is 60° C., respectively. Still further, in FIG. 7, the curve 72 represents relationship between the voltage Vds and a (light) leakage current Ioff due to the irradiation with the illumination light from the backlight device 3.

As is clear from the curves 71 and 72, in the case where the source/drain voltage Vds per one thin film transistor is about 3 V or more, the leakage current Ioff due to an increase in the ambient temperature is greater than the above-described leakage current Ioff due to the illumination light. Even if a light shielding film (the bottom gate electrode 21) was provided, the effect of the leakage current reduction by the light shielding film (the bottom gate electrode 21) was small. In other words, as shown by the conventional example, it was impossible to reduce the leakage current Ioff when the ambient temperature rose.

On the other hand, as shown by the curve 73 in FIG. 8, as the voltage Vbg applied to the bottom gate electrode 21 increases, the resistance of the low-concentration impurity-doped region 29 remarkably decreases. More specifically, when the applied voltage Vbg is set to 8 V or more, the resistance of the low-concentration impurity-doped region 29 can be reduced to half or less of the resistance thereof when the applied voltage Vbg is 0 V. This makes it possible to double, or increase more, the number of thin film transistors connected in series. In other words, the number of the thin film transistors, which is about two conventionally, can be increased to four, as in the above-described switching portion 18. As a result, for example, in the case where the maximum value of the source signal is set to 4 V and the amplitude at the common electrode 20 is 5 V, a voltage of a maximum of 9 V is applied in the switching portion 18. Therefore, the source/drain voltage Vds per one thin film transistor is 2.25 (=9/4) V in the switching portion 18. In this case, as is clear from the curves 71 and 72 shown in FIG. 7, the leakage current Ioff due to the illumination light is greater than the leakage current Ioff due to an increase in the ambient temperature. In the switching portion 18 of the present embodiment, however, the illumination light can be blocked by the bottom gate electrode 21. Therefore, even when the ambient temperature rises, the leakage current Ioff can be reduced.

It should be noted that the curve 73 shown in FIG. 8 indicates the relationship in the case where the base insulation film 22 is composed of an SiN film and an SiO₂ film having a thickness of 100 nm each. When the film thickness of this base insulation film 22 is decreased, it is possible to further achieve an effect of reducing a resistance of the low-concentration impurity-doped region 29 due to the application of a voltage to the bottom gate electrode 21.

In the switching portion (semiconductor device) 18 of the present embodiment having the above-described configuration, a silicon layer (semiconductor layer) SL is provided below the gate electrodes g1 to g4 of the plurality of thin film transistors Tr1 to Tr4 connected in series, the silicon layer SL having channel regions 30 provided with respect to the plurality of thin film transistors Tr1 to Tr4, respectively, and the low-concentration impurity-doped regions 29 adjacent to the channel regions 30. Besides, in the switching portion 18 of the present embodiment, the bottom gate electrode 21 is provided below the silicon layer SL, and the same gate signal as that for the plurality of gate electrodes g1 to g4 is supplied to the bottom gate electrode 21, whereby the resistance of the low-concentration impurity-doped region 29 can be decreased significantly. Thus, in the switching portion 18 of the present embodiment, the source/drain voltage Vds per one thin film transistor can be decreased by increasing the number of the thin film transistors connected in series, as shown in FIGS. 7 and 8. As a result, even when the ambient temperature rises, a leakage current can be surely reduced by the bottom gate electrode (light shielding film) 21. In other words, the present embodiment provides the switching portion 18 that can reduce a leakage current, irrespective of the ambient temperature.

In the switching portion 18 of the present embodiment, the resistance of the low-concentration impurity-doped region 29 can be decreased significantly. This makes it possible to prevent a decrease in the current driving power (i.e., ON current) in the switching portion 18. In other words, the switching portion 18 of the present embodiment, unlike the conventional example, can break away from the relationship of trade-off in which if a leakage current is suppressed, this causes lack of an ON current, and if an ON current is increased, this causes a leakage current to increase also. As a result, the suppression of a leakage current and the prevention of a decrease in the ON current can be achieved both.

Further, in the present embodiment, the upper light shielding film 35 is provided that is provided above the plurality of gate electrodes g1 to g4 and that shields the channel regions 30 and the low-concentration impurity-doped regions 29 from light. This makes it possible to block light from above the gate electrodes g1 to g4, using the upper light shielding film 35. As a result, an increase in a leakage current due to this light can be prevented.

Still further, the switching portion (semiconductor device) 18 that is capable of reducing a leakage current is used in the present embodiment. This makes it possible to easily configure the active matrix substrate 5 and the liquid crystal display device (display device) 1 characterized by low power consumption.

### Embodiment 2

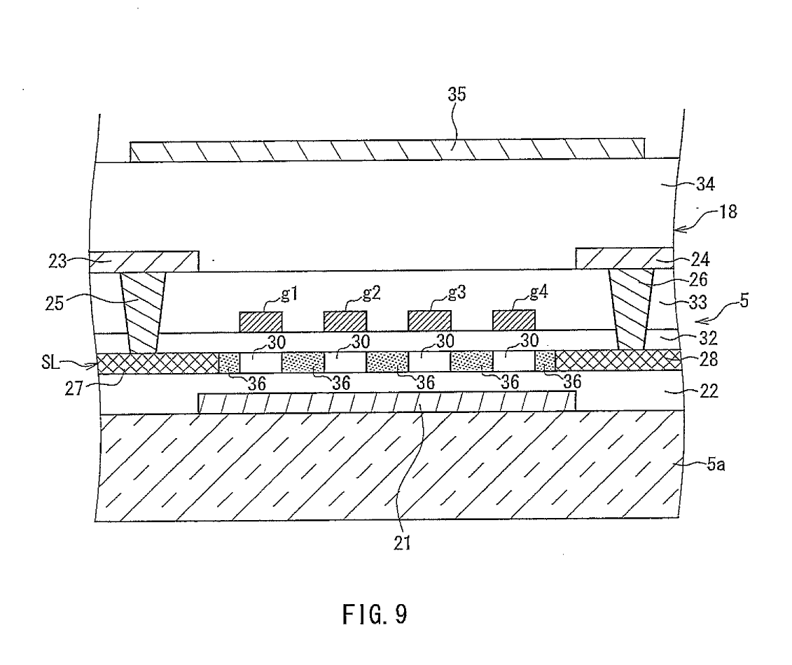

FIG. 9 is a cross-sectional view showing a specific configuration of a switching portion according to Embodiment 2 of the present invention. In FIG. 9, a main difference of the present embodiment from Embodiment 1 shown above is that in the silicon layer, the dimension of each of the plurality of low-concentration impurity-doped regions in a direction in which the plurality of thin film transistors are connected is set to a predetermined dimension or smaller. It should be noted that the elements in common with Embodiment 1 are denoted by the same reference numerals, and repetitive descriptions of the same are omitted.

More specifically, as shown in FIG. 9, the switching portion 18 of the present embodiment, the dimension of each of the plurality of low-concentration impurity-doped regions 36 in a direction in which the four thin film transistors Tr1 to Tr4 are connected (in the horizontal direction as viewed in FIG. 9) in the silicon layer (semiconductor layer) SL is set to a predetermined dimension or smaller. Thus, without high-concentration regions being provided, the four thin film transistors Tr1 to Tr4 are connected in series in the switching portion 18 of the present embodiment, unlike in Embodiment 1.

More specifically, in the switching portion 18 of the present embodiment, the dimension in the aforementioned connection direction of each of the low-concentration impurity-doped regions 36 connected to the source region 27 or the drain region 28 (i.e., the dimension of that at each end) is set to 1.5 μm, and the dimension in the aforementioned connection direction of each of the low-concentration impurity-doped regions 36 arranged between adjacent ones of the four thin film transistors Tr1 to Tr4 (i.e., the dimension of the connection portion) is set to 2.0 μm, by using an I-ray stepper of an exposure device. Such setting of dimensions causes the resistance at the low-concentration impurity-doped region 36 to be set higher, and even when the number of thin film transistors connected in series is increased, the ON current does not decrease.

More specifically, in the case where low-concentration impurity-doped regions 36 having a sheet resistance of 160 kΩ are used and a voltage of 8 V is applied to the bottom gate electrode 21, a total resistance of all the low-concentration impurity-doped region 36 is 720 kΩ (=160 kΩ/2×{1.5 μm×2 (both ends)+2.0 μm×3 (connection portions){). In other words, even when the sheet resistance at the low-concentration impurity-doped regions 36 is increased, the sheet resistance of the low-concentration impurity-doped region 36 is decreased to ½ by the voltage application to the bottom gate electrode 21, and therefore, the ON current does not decrease. Further, the total resistance of 720 kΩ of all the low-concentration impurity-doped regions 36 is equivalent to that of the product having the conventional configuration in which three thin film transistors that has low-concentration impurity-doped regions having a sheet resistance set to 80 kΩ are connected in series. Thus, this proves that, in the present embodiment, even when the number of thin film transistors to be connected in series is increased, the ON current dos not decrease.

With the above-described configuration, the present embodiment can achieve the same operation and effect as those of Embodiment 1 described above. Further, in the switching portion 18 of the present embodiment, the dimensions of the plurality of low-concentration impurity-doped regions 36 in the connection direction of the plurality of thin film transistors Tr1 to Tr4 are set to predetermined dimensions or smaller in the silicon layer LS. In the switching portion 18 of the present embodiment, this configuration makes it possible to prevent a decrease in the ON current, even when the resistance of the low-concentration impurity-doped regions 36 is set higher and the number of thin film transistors connected in series is increased. Even if the number of thin film transistors connected in series is increased, the total of resistances of the low-concentration impurity-doped regions 36 can be prevented from increasing. The ratio of an area occupied by the thin film transistors Tr1 to Tr4 in the switching portion 18 can be decreased.

### Embodiment 3

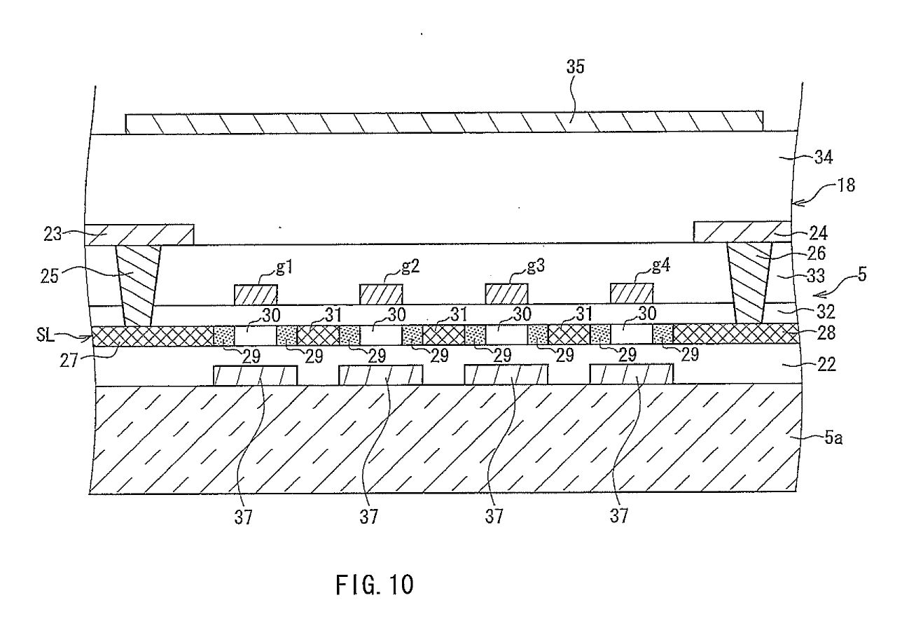

FIG. 10 is a cross-sectional view showing a specific configuration of a switching portion according to Embodiment 3 of the present invention. In FIG. 10, a main difference of the present embodiment from Embodiment 1 shown above is that a plurality of bottom gate electrodes are provided with respect to the plurality of transistors, respectively, below the channel region and the low-concentration impurity-doped regions. It should be noted that the elements in common with Embodiment 1 are denoted by the same reference numerals, and repetitive descriptions of the same are omitted.

More specifically, as shown in FIG. 10, in the switching portion 18 of the present embodiment, a bottom gate electrode 37, divided into four pieces, is provided. These pieces of the bottom gate electrode 37 are formed so as to correspond to the plurality of thin film transistors Tr1 to Tr4, respectively, below the channel regions 30 and the low-concentration impurity-doped regions 29. The bottom gate electrode 37 is different from that of Embodiment 1 in that each piece of the same is capacitively coupled with a corresponding one of the gate electrodes g1 to g4. Thus, the voltage application to each piece of the bottom gate electrode 37 is carried out by capacity coupling. In other words, in the switching portion 18 of the present embodiment, the supply of a voltage signal to each piece of the bottom gate electrode 37 is carried out, without any bottom gate line.

In the present embodiment, the above-described configuration makes it possible to achieve the same operation and effect as those of Embodiment 1 described above. Besides, in the present embodiment, the bottom gate electrode 37 is divided into a plurality of pieces so that the pieces are provided with respect to the plurality of thin film transistors Tr1 to Tr4, respectively, below the channel regions 30 and the low-concentration impurity-doped regions 29. This allows the bottom gate electrode 37 to be provided only at portions that contribute to the light blocking and the reduction of resistances of the low-concentration impurity-doped regions 29 in the present embodiment. As a result, the configuration of the switching portion 18 can be simplified. Further, the voltage application to each piece of the bottom gate electrode 37 is carried out by the capacity coupling with the corresponding gate electrodes g1 to g4, respectively, and therefore, load capacitances of the respective gate electrodes g1 to g4 can be reduced.

### Embodiment 4

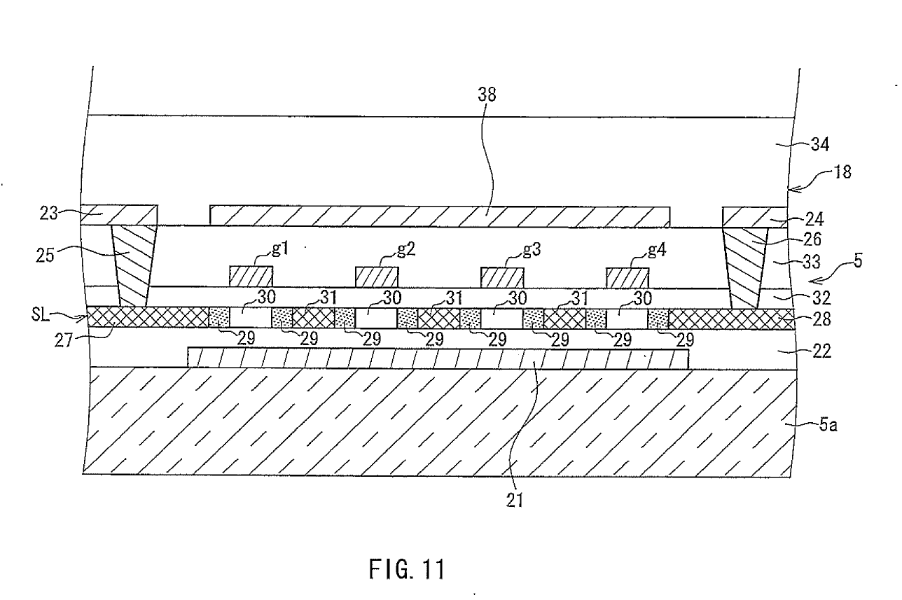

FIG. 11 is a cross-sectional view showing a specific configuration of a switching portion according to Embodiment 4 of the present invention. In FIG. 11, a main difference of the present embodiment from Embodiment 1 described above is that an upper light shielding film is formed with the same material as that of the source electrode and the drain electrode, and that a signal in the same phase as that for the plurality of gate electrodes is supplied to the upper light shielding film. It should be noted that the elements in common with Embodiment 1 are denoted by the same reference numerals, and repetitive descriptions of the same are omitted.

More specifically, as shown in FIG. 11, in the switching portion 18 of the present embodiment, an upper light shielding film 38 is formed on the first interlayer film 33 with the same material in the same layer as those for the source electrode 23 and the drain electrode 24. The upper light shielding film 38 is formed so as to overlap the plurality of gate electrodes g1 to g4 in the vertical direction. This causes the upper light shielding film 38 to be capacitively coupled with the gate electrodes g1 to g4. By this capacity coupling of the upper light shielding film 38 with the gate electrodes g1 to g4, a signal in the same phase as that for the gate electrodes g1 to g4 is supplied to the upper light shielding film 38.

With the above-described configuration, the present embodiment can achieve the same operation and effect as those of Embodiment 1 described above. Besides, in the present embodiment, the upper light shielding film 38 is formed with the same material in the same layer as those for the source electrode 23 and the drain electrode 24. Therefore, the upper light shielding film 38, the source electrode 23, and the drain electrode 24 can be formed at the same time. As a result, the switching portion (semiconductor device) 18 that can be fabricated easily can be configured more easily.

In the present embodiment, since a signal in the same phase as that for the plurality of gate electrodes g1 to g4 is supplied to the upper light shielding film 38, the resistance of the low-concentration impurity-doped regions 29 when the thin film transistors Tr1 to Tr4 are in an ON state can be decreased further. This makes it possible to increase the number of thin film transistors connected in series easily. As a result, a leak current can be decreased further. Besides, the current driving power (ON current) of the thin film transistors can be increased easily.

It should be noted that in the switching portion 18, a signal should be at least supplied to the light shielding film 38 in a state in which a signal is being supplied to the gate electrodes g1 to g4. Therefore, the signal supplied to the gate electrodes g1 to g4 (gate electrode signal), and the signal supplied to the upper light shielding film 38 (upper light shielding film signal) may be identical to each other in the magnitude of the driving voltage, the rising time, and the falling time, or may be different in at least one of the magnitude of the driving voltage, the rising time, and the falling time. Incidentally, the case where the gate electrode signal and the upper light shielding film signal are identical to each other in the magnitude of the driving voltage, the rising time, and the falling time refers to, for example, a case where the upper light shielding film signal has, as its signal waveform, the signal waveform of the bottom gate electrode signal shown in FIG. 4.

Here, the falling time of the upper light shielding film signal is preferably different from that of the gate electrode signal. More specifically, the upper light shielding film may fall after the gate electrode signal falls, or alternatively, the gate electrode signal may fall after the upper light shielding film signal falls. Incidentally, the case where the upper light shielding film signal falls after the gate electrode signal falls refers to, for example, a case where the upper light shielding film signal has, as its signal waveform, the signal waveform of the bottom gate electrode signal shown in FIG. 5.

Further, in the present embodiment, the upper light shielding film 38 is capacitively-coupled with each of the plurality of gate electrodes g1 to g4. With this, the load capacities of the plurality of gate electrodes g1 to g4 can be reduced.

It should be noted that all the aforementioned embodiments are exemplary, and do not limit the present invention. The technical scope of the present invention is defined by the claims, and all of modifications in the scope equivalent to the configurations described in the claims fall in the technical scope of the present invention as well.

For example, the above-described explanation refers to, as an exemplary case, a case where the present invention is applied to the switching portion for the pixel electrode used in the active matrix substrate for a liquid crystal display device. However, the semiconductor device of the present invention is not limited at all, as long as it is a semiconductor device that includes: a plurality of thin film transistors connected in series; gate electrodes that are provided in the plurality of thin film transistors, respectively; a semiconductor layer provided below a plurality of the gate electrodes; channel regions formed in the semiconductor layer, the channel regions being provided in the plurality of thin film transistors, respectively; low-concentration impurity-doped regions formed in the semiconductor layer, the low-concentration impurity-doped regions being adjacent to the channel regions; a bottom gate electrode provided below the channel regions; and a light shielding film that shields the channel regions and the low-concentration impurity-doped regions from light, wherein, in a state where a voltage is being applied to the gate electrodes, a voltage is applied to the bottom gate electrode. More specifically, for example, the present invention can be applied to a display device of various types, such as semi-transmissive-type or reflection type liquid crystal panel, an organic EL (electronic luminescence) element, an inorganic ET, element, or a field emission display, and to an active matrix substrate used therein. Besides, the semiconductor device of the present invention can be applied to, other than the switching portion for the pixel electrode, a switching portion used in a peripheral circuit such as a driver circuit. Further, the number of the transistors connected in series is not limited to four in the aforementioned case.

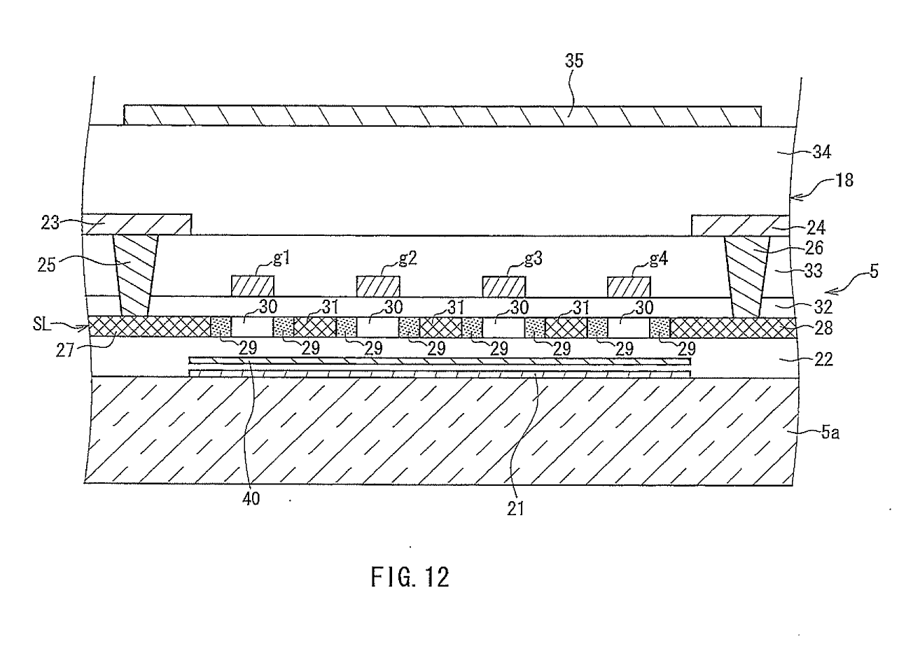

Further, the above description explains a case where the bottom gate electrode is used as a light shielding film, but the present invention is not limited to this at all. More specifically, as shown in FIG. 12, the configuration may be such that a transparent electrode is used for forming the bottom gate electrode 21, and a light shielding film 40 is provided below the semiconductor layer SL and below the bottom gate electrode 21. In such a configuration, the base insulation film 22 has a laminate structure.

It is, however, preferable that the bottom gate electrode functions also as the light shielding film, as in the above-described embodiments, because in this case, it is possible to prevent the structure of the semiconductor device from becoming complex and bulky, and it is possible to easily configure the semiconductor device that can be fabricated easily.

Further, the explanations of Embodiments 1, 2, and 4 refer to a case where the bottom gate line is connected to the bottom gate electrode and the same gate signal as that supplied to the plurality of gate electrodes is supplied to the bottom gate electrode. However, the semiconductor device of the present invention may have any configuration as long as a voltage is applied to the bottom gate electrode in a state where a voltage is being applied to the gate electrode. More specifically, signals of different voltage in the same phase may be supplied to the bottom gate electrode and each gate electrode, respectively. Further, it is preferable that a signal that is different from the signal supplied to each of the plurality of gate electrodes in at least the falling time is supplied to the bottom gate electrode; that is, gate signals causing a transistor to turn on during times that overlap each other and causing the transistor to turn off at different times from each other are supplied to the gate electrodes and the bottom gate electrode, respectively. This is because the problem of an increase in fluctuations of a pixel voltage that occur when the gate signal causes the transistor to turn off (so-called field-through phenomenon) can be avoided.

Further, the bottom gate electrode and the gate electrodes may be capacitively coupled as in Embodiment 3 so that by supplying a gate signal to each gate electrode, the signal in the same phase should be supplied to the bottom gate electrode. In the case where the electrodes are capacitively coupled in this way, the provision of a bottom gate line can be omitted.

Further, the explanation of Embodiment 4 refers to the case where a signal in the same phase as that of a signal supplied to each of the plurality of gate electrodes is supplied to the upper light shielding film, but the present invention is not limited to this. A signal that is different from the signal supplied to the plurality of gate electrodes regarding at least the falling time may be supplied to the upper light shielding film. Such a configuration is preferable, since the problem of an increase in fluctuations of a pixel voltage that occur when the gate signal causes the transistor to turn off (so-called field-through phenomenon) can be avoided.

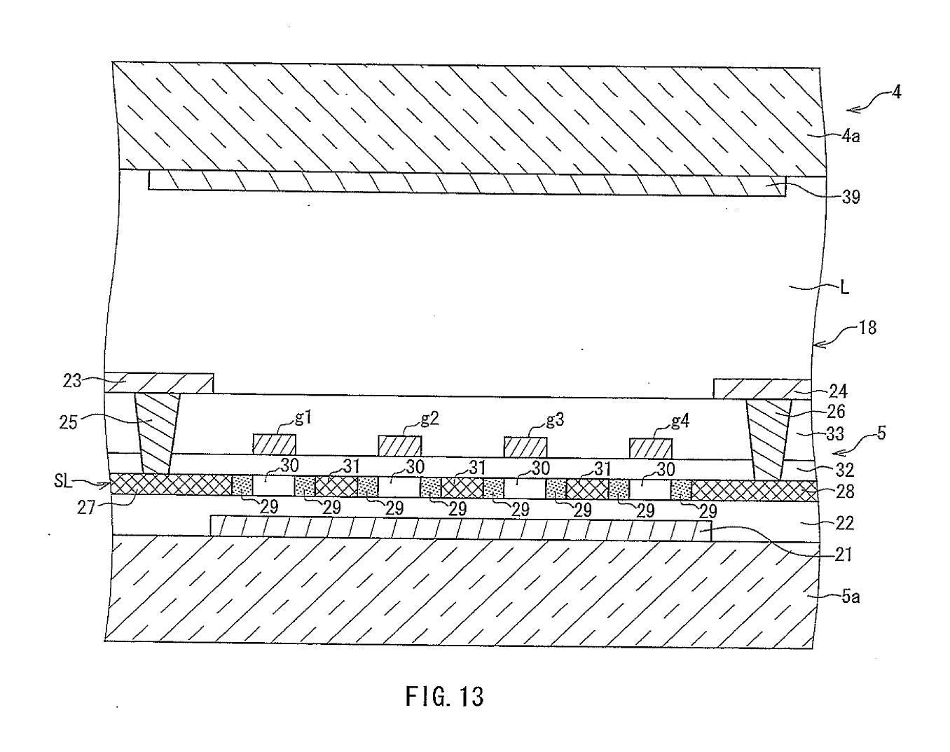

Still further, the above explanation refers to the case where the upper light shielding film is provided on the active matrix substrate, but the configuration of the upper light shielding film of the present invention is not limited to this. The upper light shielding film may be provided on the color filter substrate. More specifically, as shown in FIG. 13, the upper light shielding film 39 is formed on a liquid crystal layer L side surface of the substrate main body 4a in the color filter substrate 4. The upper light shielding film 39 may shield at least the channel regions 30 and the low-concentration impurity-doped regions of the respective transistors.

Further, other than the configurations described to above, configurations obtained by combining some of Embodiments 1 to 4 appropriately may be used.

### INDUSTRIAL APPLICABILITY

The present invention is useful for a semiconductor device that can achieve leakage current reduction irrespective of an ambient temperature, an active matrix substrate in which such a semiconductor device is used, and a display device.

1. A semiconductor device comprising:
a plurality of thin film transistors connected in series;
gate electrodes that are provided in the plurality of thin film transistors, respectively;
a semiconductor layer provided below a plurality of the gate electrodes;
channel regions formed in the semiconductor layer, the channel regions being provided in the plurality of thin film transistors, respectively;
low-concentration impurity-doped regions formed in the semiconductor layer, the low-concentration impurity-doped regions being adjacent to the channel regions;
a bottom gate electrode provided below the channel regions; and
a light shielding film that shields the channel regions and the low-concentration impurity-doped regions from light,
wherein, in a state where a voltage is being applied to the gate electrodes, a voltage is applied to the bottom gate electrode.

2. The semiconductor device according to claim 1, wherein the application of the voltage to the gate electrodes, and the application of the voltage to the bottom gate electrode, start at the same time.

3. The semiconductor device according to claim 1, wherein the application of the voltage to the gate electrodes, and the application of the voltage to the bottom gate electrode, end at different times, respectively.

4. The semiconductor device according to claim 1, wherein the bottom gate electrode also functions as the light shielding film.

5. The semiconductor device according to claim 1, wherein the light shielding film is a lower light shielding film that is provided below the semiconductor layer and shields the channel regions and the low-concentration impurity-doped regions from light.

6. The semiconductor device according to claim 1, wherein the light shielding film is an upper light shielding film that is provided above the semiconductor layer and shields the channel regions and the low-concentration impurity-doped regions from light.

7. The semiconductor device according to claim 6, wherein, in a state where a voltage is being applied to the gate electrodes, a voltage is applied to the upper light shielding film.

8. The semiconductor device according to claim 7, wherein the application of the voltage to the gate electrodes, and the application of the voltage to the upper light shielding film, start at the same time.

9. The semiconductor device according to claim 7, wherein the application of the voltage to the gate electrodes, and the application of the voltage to the upper light shielding film, end at different times, respectively.

10. The semiconductor device according to claim 6, further comprising:
a source electrode provided at an end side of the semiconductor layer; and
a drain electrode provided at the other end side of the semiconductor layer,
wherein the upper light shielding film is formed with the same material in the same layer as those for the source electrode and the drain electrode.

11. The semiconductor device according to claim 6, wherein the gate electrodes and the upper light shielding film are formed so as to overlap each other in a vertical direction, whereby the gate electrodes and the upper light shielding film are capacitively coupled with each other.

12. The semiconductor device according to claim 1, wherein, in the semiconductor layer, a dimension of each of the low-concentration impurity-doped regions in a direction in which the plurality of thin film transistors are connected is set to a predetermined dimension or smaller.

13. The semiconductor device according to claim 1, wherein the bottom gate electrode is divided into a plurality of pieces so that the pieces are located below the channel regions, respectively.

14. An active matrix substrate in which the semiconductor device according to claim 1 is used.

15. A display device in which the semiconductor device according to claim 1 is used.
